(19) United States
(12) Patent Application Publication
(10) Pub. No.: US 2024/0347092 A1
(43) Pub. Date: Oct. 17, 2024

(54) Ferroelectric Latch Adapted to Replace a Conventional Latch

(71) Applicant: Radiant Technologies, Inc., San Ramon, CA (US)

(72) Inventor: Joseph T Evans, JR., Albuquerque, NM (US)

(73) Assignee: Joseph T Evans, JR., Albuquerque, NM (US)

(21) Appl. No.: 18/637,291

(22) Filed: Apr. 16, 2024

Related U.S. Application Data
(60) Provisional application No. 63/460,002, filed on Apr. 17, 2023.

(51) Int. Cl. G11C 11/22

(52) U.S. Cl. CPC G11C 11/2297; G11C 11/221

(57) ABSTRACT

A ferroelectric latch that includes first and second autonomous memory cells. The first autonomous memory cell has a first current controller that controls a first current that flows between a first node and a power rail. The first autonomous memory cell includes a first ferroelectric capacitor connected to the first node and the first current controller input; and a first conductive load connected to the first node and a second power rail. The second autonomous memory cell includes a second current controller that controls a second current that flows between a second node and the power rail; a second ferroelectric capacitor connected to the second node and the second current controller input, and a second conductive load connected to the second node and the second power rail. The first node is connected to the second current controller input, and the second node is connected between the first current controller input and the second node.

### RELATED APPLICATIONS

This patent application claims priority from U.S. provisional patent application 63/460,002 filed Apr. 17, 2023.

### BACKGROUND

Logic circuits that must operate across power disruptions are known to the art. However, converting an existing circuit that is not designed to operate across a power disruption to a circuit that can operate across a power disruption poses significant challenges.

The simplest form of such circuits utilizes some form of energy storage such as a battery to maintain the state of the system during the period in which the power that normally runs the circuit is off. Such systems are limited by the amount of power that can be stored. Some circuitry prolongs the period over which external power is not needed by entering a low power mode that maintains the state of the circuitry for an extended period of time.

A second class of circuits stores the state of the system in a non-volatile memory prior to powering down in the event of a power disruption. When power is restored, the system state is “reloaded” from the non-volatile memory and system operation continues. This type of system typically requires a separate save/restore mode. In one class of systems, the non-volatile memory that stores the state operates at different logic levels or frequencies than the circuitry whose state is being saved. For example, the non-volatile memory could be an EEPROM that operates as a shadow RAM. The voltages and cycle times needed to store information into the non-volatile memory are substantially different from those used by the logic circuits, and hence, the non-volatile memory cannot track the state of the system in real time such that the state of the system is always stored in the non-volatile memory. In addition, the save cycle requires a separate system mode that adds complexity and cost to the system.

A second class of non-volatile memory is based on ferroelectric memory devices. These devices operate at the same logic levels as the other circuitry, and can be read and written in times comparable to those of the logic circuitry. However, these non-volatile memory devices must be read and written synchronously, and hence, using such non-volatile memory devices for storing and restoring the state of the system still typically involves a separate save/restore procedure. Further, since these memories can be written by voltages that are within the normal logic levels of the associated circuitry, preventing alteration of the data stored therein during periods of power instability such as during power down or power up poses significant challenge.

### SUMMARY

A ferroelectric latch that includes first and second autonomous memory cells is disclosed. The first autonomous memory cell characterized by a first current controller having by a first current controller input that controls a first current that flows between a first node and a power rail. In addition, the first autonomous memory cell includes a first ferroelectric capacitor connected to the first node and the first current controller input; and a first conductive load connected to the first node and a second power rail.

The second autonomous memory cell includes a second current controller characterized by a second current controller input that controls a second current that flows between a second node and the power rail; a second ferroelectric capacitor connected to the second node and the second current controller input, and a second conductive load connected to the second node and the second power rail, the first node is connected to the second current controller input, and the second node is connected between the first current controller input and the second node.

In another aspect, the ferroelectric latch includes a first gate connected to the first node, the first gate connecting the first node to a signal line and is controlled by a device external to the ferroelectric latch.

In another aspect, the first and second current controllers comprise NPN transistors.

In another aspect, the first and second current controllers comprise CMOS transistors.

In another aspect, the first current controller includes the CMOS transistors connected as a first current mirror.

In another aspect, the first and second current controllers comprise current mirrors.

In another aspect, the first current mirror is characterized by a clamp voltage and the first current controller further includes a current limiter that limits current entering the first current controller input, such that a maximum potential across the ferroelectric capacitors is greater than a clamp voltage of the current mirrors.

In another aspect, the first and second current controllers comprise bipolar transistors.

In another aspect, the first and second current controllers comprise ferroelectric field effect transistors (FFETs).

In another aspect, the first and second current controllers comprise FFETs configured as a current mirror

In another aspect, the first conducting load includes an FFET.

In another aspect, the ferroelectric latch includes a first power gate configured to disconnect the ferroelectric latch from a first power rail in response to a first disconnect signal on a first bus.

In another aspect, the ferroelectric latch includes first and second latch gates, each of the latch gates having an input and an output, the input of the first latch gate is connected to the output of the second latch gate, and the output of the first latch gate is connected to the input of the second latch gate, the first ferroelectric capacitor is connected between the input and output of the first latch gate and the second ferroelectric capacitor is connected to the input and output of the second latch gate; and a second power gate configured to disconnect the first latch gate from the first power rail in response to a second disconnect signal on a second bus.

### BRIEF DESCRIPTION OF THE DRAWINGS

FIG. 1 illustrates the basic operation of an autonomous memory cell.

FIG. 2 is a schematic drawing of a ferroelectric autonomous memory circuit of the type shown in FIG. 1 which utilizes as the current controller an NPN transistor having a base resistance.

FIG. 3 illustrates the potential on the power rail and on node 49 shown in FIG. 2 as a function of time when the ferroelectric capacitor is initially polarized in either the up or down state.

FIG. 4 illustrates a CMOS embodiment of an autonomous memory cell.

FIG. 5 illustrates a ferroelectric latch that can be used to replace a conventional volatile latch to provide continuity across a power disruption.

FIG. 6 illustrates a ferroelectric latch that is implemented in CMOS.

FIG. 7 illustrates a ferroelectric latch according to one embodiment of the present disclosure that is implemented in CMOS and includes current limiters.

FIG. 8 illustrates another exemplary embodiment of a ferroelectric latch according to the present disclosure.

FIG. 9 illustrates a ferroelectric latch based on bipolar transistor technology.

FIG. 10 is a cross-sectional view of one embodiment of a FFET according to the present disclosure.

FIG. 11 illustrates a current controller that could, in principle, be used for the current controllers shown in FIG. 5.

FIG. 12 illustrates a ferroelectric latch according one embodiment of the present disclosure.

FIG. 13 illustrates a transparent latch that has been altered to store the current state of the latch output in two ferroelectric capacitors.

FIG. 14 illustrates a CMOS compound latch.

FIG. 15 illustrates an embodiment of a multiple bit compound latch that can store and retrieve a plurality of data bits.

### DETAILED DESCRIPTION

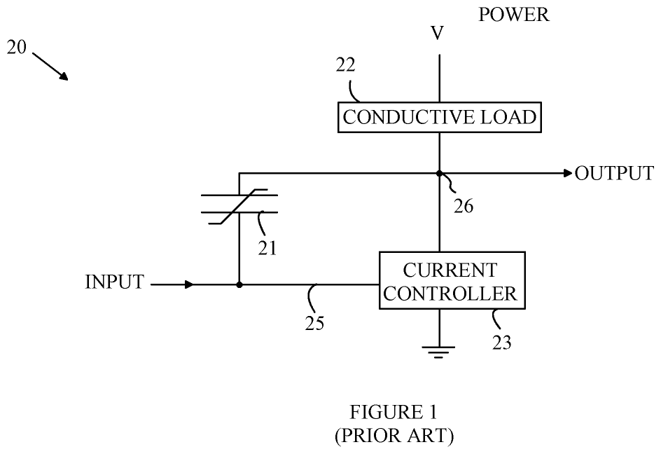

The manner in which a latch according to the present disclosure provides its advantages can be more easily understood with reference to FIG. 1, which illustrates the basic operation of an autonomous memory cell. Autonomous memory circuit 20 includes a ferroelectric capacitor 21 and a current controller 23 having a current controller input 25. A conductive load 22 is connected between a power rail and current controller 23. For the purposes of this disclosure, an autonomous memory is defined to be any circuit that is of the form shown in FIG. 1 in which the output of the circuit is a voltage.

Ferroelectric capacitor 21 has a remanent polarization that can be switched by applying a voltage across ferroelectric capacitor 21. That is, in the absence of a voltage across the capacitor, the dielectric of the capacitor is electrically polarized. For the purpose of this discussion, it will be assumed that the dielectric has two states corresponding to the dielectric being polarized either up or down. If a voltage is applied across the ferroelectric capacitor, an electric field is created in the ferroelectric capacitor. If the field direction is the same as that of the remanent polarization, a small current flows in the circuit connecting the two plates of the ferroelectric capacitor. If, on the other hand, the applied electric field is in a direction opposite to that of the remanent polarization, the remanent polarization will change direction to conform to the new field direction, and a large current will flow in the external circuit. The magnitude of the current and the voltage at which it flows can be set by adjusting the composition, area, and thickness of the ferroelectric capacitor and the properties of current controller 23. Current controller 23 is an analog device in which the magnitude of the current flowing between node 26 and ground depends on the magnitude of the current entering current controller input 25. The larger the current entering current controller input 25, the larger the current passing through the current controller.

A number of different circuit elements can be utilized for current controller 23; for example, current controller 23 can be constructed with field effect transistors or other types of transistors. In addition, current controller 23 can be constructed from a current mirror.

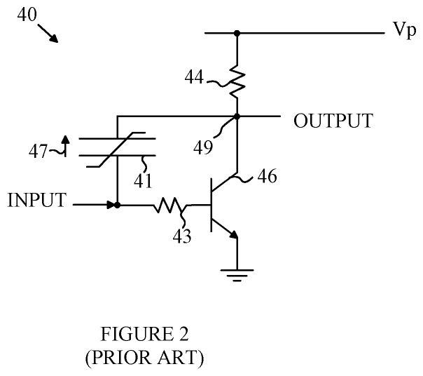

Refer now to FIG. 2 which is a schematic drawing of a ferroelectric autonomous memory circuit 40 of the type shown in FIG. 1 which utilizes as the current controller an NPN transistor 46 having a base resistance 43. The conductive load is a resistor 44. On power up, any charge displaced from ferroelectric capacitor 41 must pass through the Base/Emitter circuit of NPN transistor 46 to ground, causing a greater conduction of current through the Collector/Emitter path of the transistor. If ferroelectric capacitor 41 starts down, it will switch to the up state during power up. The switching time of ferroelectric capacitor 41 is determined both by the restriction of resistor 44 and by the amplification of the ferroelectric charge by NPN transistor 46 attempting to prevent the capacitor from switching. After power up, the state of ferroelectric capacitor 41 will be in the up polarization state as indicated by arrow 47.

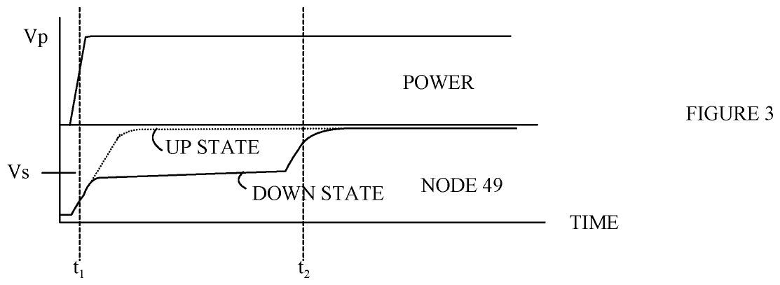

Refer now to FIG. 3, which illustrates the potential on the power rail and on node 49 shown in FIG. 2 as a function of time when the ferroelectric capacitor is initially polarized in either the up or down state. If ferroelectric capacitor 41 is in the down state when ferroelectric autonomous memory circuit 40 is powered up, the potential on node 49 initially increases with the power rail potential until the potential at node 49 reaches a value that causes ferroelectric capacitor 41 to begin to change polarization state. As ferroelectric autonomous memory circuit 40 is powered up with ferroelectric capacitor 41 in the down state, ferroelectric capacitor 41 begins to flip polarization, and charge is released that causes NPN transistor 46 to begin to conduct. If NPN transistor 46 begins to conduct too much, the potential on node 49 begins to drop and ferroelectric capacitor 41 slows its switching. If NPN transistor 46 does not conduct enough, the potential on node 49 rises faster causing ferroelectric capacitor 41 to switch faster forcing more current into the control input of NPN transistor 46 increasing its conductivity. Thus, the circuit stabilizes with the potential of node 49 at a specific intermediate value with a slow rate of rise. In this manner, the change in conductivity of NPN transistor 46 limits the voltage rise at node 49 until the change in state of ferroelectric capacitor 41 is completed. At this point, no further switching charge will be released from ferroelectric capacitor 41, and hence, NPN transistor 46 will again become non-conducting. The potential during the transition of ferroelectric capacitor 41 will be referred to as the “shelf voltage”, Vₛ, in the following discussion. The specific shape of the potential at node 49, or the analogous node in autonomous memory circuits based on other forms of current controllers, will, in general, depend on the specific current controller implementation, and the relationships between the current controller, and the ferroelectric capacitor. In general, the length in time at which the shelf voltage is present is related to the time that it takes for the charge on the capacitor to move from one plate of the capacitor to the other.

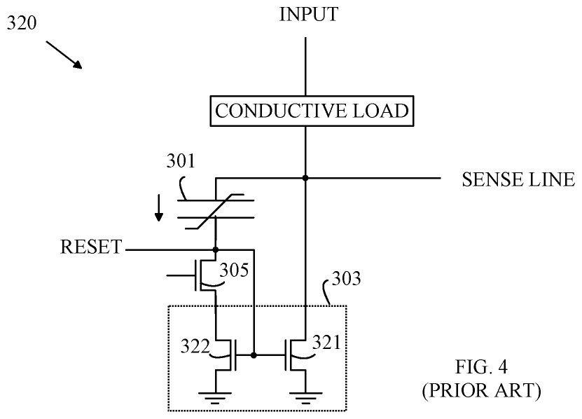

Refer now to FIG. 4, which illustrates a CMOS embodiment of an autonomous memory cell. In autonomous memory cell 320, current controller 303 is implemented as a current mirror consisting of field effect transistors (FETs) 321 and 322. Hence, the current passing through FET 321 is a set fraction of the current leaving ferroelectric capacitor 301, which passes through FET 322. The ratio of the two currents is determined by the ratio of the widths of the two FETs if the channel lengths are the same. In one exemplary embodiment, FET 322 has a width that is 15 times less than that of FET 321. In this case, FET 321 mirrors 15 times the current forced through FET 322 by ferroelectric capacitor 301. During the resetting of ferroelectric capacitor 301, FET 305 is non-conducting and the RESET voltage turns on FET 321 to provide a path to ground for charge coming from ferroelectric capacitor 301 as it switches to the DOWN state. When data is being written into ferroelectric capacitor 301, FET 305 is in the conducting state so the current flow through FET 322 controls the conductivity of FET 321.

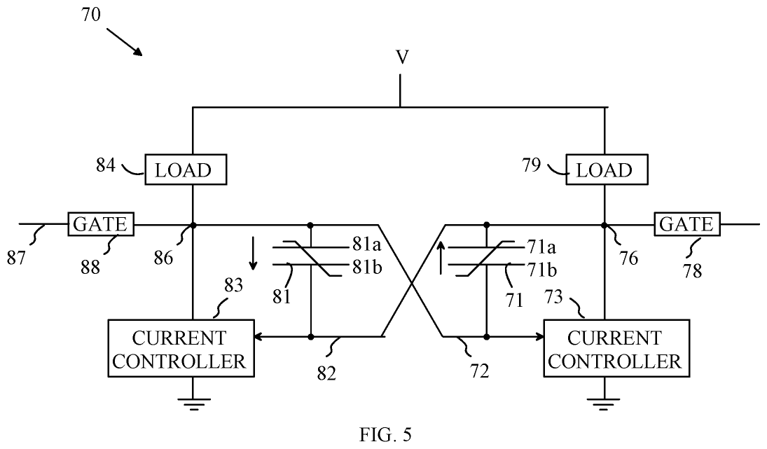

Refer now to FIG. 5, which illustrates a ferroelectric latch that can be used to replace a conventional volatile latch to provide continuity across a power disruption. Ferroelectric latch 70 can be viewed as a circuit in which two autonomous memory circuits of the type shown in FIG. 1 are connected such that the ferroelectric capacitors are forced to be in opposite states of polarization. The first autonomous memory circuit consists of ferroelectric capacitor 71, current controller 73, and load 79. The second autonomous memory circuit consists of ferroelectric capacitor 81, current controller 83, and load 84. Each autonomous memory circuit is characterized by an output node and control input. The output nodes are shown at 76 and 86. The control inputs are shown at 72 and 82. The ferroelectric capacitor in each autonomous memory circuit is connected between the output node of that autonomous memory circuit and the control input of that autonomous memory circuit. In addition, the output of each autonomous memory circuit is connected to the control input of the other autonomous memory circuit. This arrangement ensures that the ferroelectric capacitor in one autonomous memory circuit will be in the up state, and the ferroelectric capacitor in the other autonomous memory circuit will be in the down state.

Assume that ferroelectric latch 70 is storing one bit and power is lost. It will be assumed that gates 78 and 88 are open at the time of the power disruption and that ferroelectric capacitor 81 is in the down state at the time of the disruption as indicated by the arrow next to ferroelectric capacitor 81. When power is returned, node 76 will quickly rise to V, since ferroelectric capacitor 71 is polarized in the up direction, and hence, very little current will flow into current controller 73 via load 79. Since ferroelectric capacitor 81 is in the down state, the voltage at node 86 will rise to the shelf voltage, which is significantly less than V. Hence, ferroelectric capacitor 81 will be subjected to a voltage that maintains the polarization in the down state during the shelf voltage period. Once node 76 has re-established its steady state voltage, that voltage, which is applied to the control input of current controller 83 forces ferroelectric capacitor 81 to the down state.

For this example, it will be assumed that gate 88 is the latch enable gate; however, since the ferroelectric latch is symmetric, gate 78 could also be used for this function. To write a value on line 87 to ferroelectric latch 70, gate 88 is placed in the conducting state. If ferroelectric capacitor 81 is polarized in the down state, and the value on line 87 is high, a voltage that causes both ferroelectric capacitor 81 and ferroelectric capacitor 71 to flip states will be applied to the ferroelectric capacitors. Consider the case in which ferroelectric capacitor 81 is polarized in the down state as shown by the arrow when a high level is coupled onto node 86 when gate 88 is conducting. The positive voltage will force charge off of plate 81b that will exit through current controller 83.

Now consider the case in which the voltage applied to line 87 is 0. The source of the signal must be able to hold node 86 at 0. The input to current controller 73 is 0, and current controller 73 is off. Hence, node 76 will be at V. This applies a voltage across ferroelectric capacitor 81 which causes ferroelectric capacitor 81 to maintain its down polarization state.

As long as voltage is applied to ferroelectric latch 70, current will flow through the current controller associated with the ferroelectric capacitor that is in the down state. Again consider the case in which node 86 is low. To change the state of ferroelectric latch 70, a positive voltage is applied to the input of gate 88. The source for this input voltage must be able to supply sufficient power to raise the voltage of node 86 in spite of the fact that current controller 83 is conducting. Hence, current controller 83 must include some form of current limiter even when the current controller is conducting. The same limitation applies to current controller 73. The manner in which this current limitation is implemented will, in general, depend on the specifics of the current controllers in question.

As long as ferroelectric latch 70 is connected to power, ferroelectric latch 70 will draw current. It should be noted that ferroelectric latch 70 can be written when power is off, and hence, embodiments in which ferroelectric latch 70 is only powered up in advance of a read operation can be constructed to reduce the power consumption. When ferroelectric latch 70 is not connected to power, a positive pulse to node 86 will set ferroelectric capacitor 81 to the up state. Similarly, a positive pulse to node 76 will set ferroelectric capacitor 71 to the up state and ferroelectric capacitor 81 to the down state. Since neither current controller is conducting when power is not applied to ferroelectric latch 70, the write pulses do not need to have sufficient power to saturate the current controller limiters.

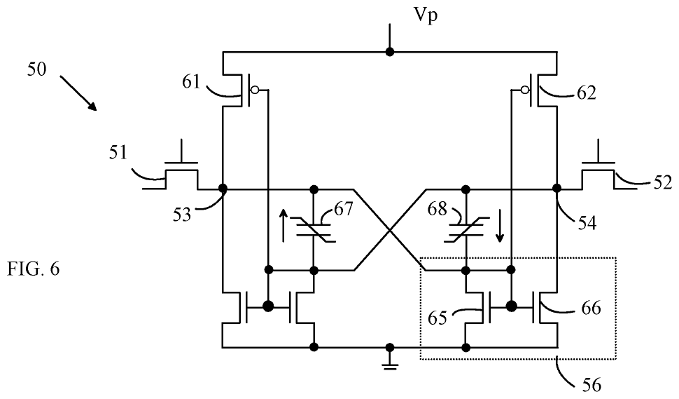

Refer now to FIG. 6, which illustrates a ferroelectric latch 50 that is implemented in CMOS. In ferroelectric latch 50, the current controllers discussed above are implemented as current mirrors. The loads are provided by gates 61 and 62. Consider the case in which ferroelectric capacitors 67 and 68 are polarized in the direction shown by the arrows next to each capacitor. In this case, node 53 would be high and node 54 would be low. Assume that power is lost when ferroelectric latch 50 is so polarized. The directions of polarization of the ferroelectric capacitors remain the same during the period in which power is not applied to the circuit. When power returns, it will be assumed that gates 51 and 52 are non-conducting. When power is restored, nodes 53 and 54 will attempt to rise. Since ferroelectric capacitor 67 is polarized in the up direction, node 53 can rise with little or no delay. Ferroelectric capacitor 68 is in the down state, and hence, node 54 cannot rise until after the polarization of node 53 switches. As a result, node 54 assumes a shelf voltage. The high voltage from node 53 propagates to the current mirror consisting of transistors 65 and 66, resulting in that current mirror entering a conducting state, which further lowers the voltage on node 54. Hence, ferroelectric capacitor 68 is connected between two voltages that polarize ferroelectric capacitor 68 in the down direction. Accordingly, ferroelectric latch 50 returns to the state that it had prior to the power interruption.

As noted above, the current controllers in the ferroelectric latch 50 are implemented as current mirrors. Refer to current mirror 56. The input to this current controller includes a short diode to ground, since the source of transistor 65 is connected to the gate of transistor 65 leaving the diode connection between the gates of transistor 65 and the drain of transistor 65. The maximum voltage that can be maintained at the input to current mirror 56 is the clamp voltage of this diode. For conventional CMOS circuits, the clamp voltage is approximately 0.7 V. Hence, ferroelectric capacitor 68 must be able to switch states at a voltage that is less than the clamp voltage.

In addition, if node 53 is high during the operation of the latch, current mirror 56 will draw current both through the input to that current mirror and the current flowing through transistor 66. If the voltage on node 53 is above the clamp voltage of transistor 64 and transistor 65, that current can be significant. The clamp voltage poses challenges in designs that utilize such conventional CMOS implementations.

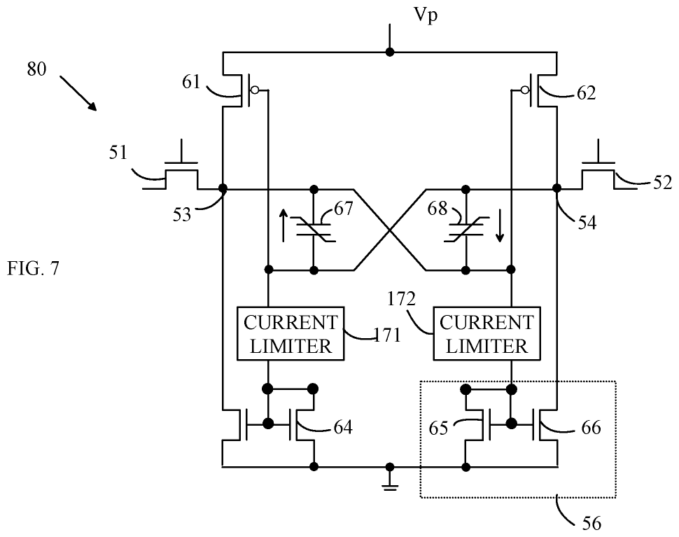

One solution to the current draw problem discussed above is to place a current limiter in the control input to the current mirror. Refer now to FIG. 7, which illustrates a ferroelectric latch 80 according to one embodiment of the present disclosure that is implemented in CMOS and includes such current limiters. To simplify the following discussion, those elements of ferroelectric latch 80 that serve functions analogous to those served by corresponding elements in ferroelectric latch 50 have been given the same numeric designations and will not be discussed further here.

Each of the current mirrors in ferroelectric latch 80 has a current limiter in series with the control input of that current mirror. The current limiters are shown at 171 and 172. The current limitation is chosen such that the input voltage to each current mirror does not reach the clamp voltage of the diode at the input even when the input is connected to a voltage of Vp. For example, the difference in voltage between the potential on node 54 when the node is at, or near, Vp and the input to transistor 64 appears across current limiter 171. This results in reduced current flow through the current mirror and an increase in the voltage across ferroelectric capacitor 67. The increased voltage allows ferroelectric capacitors that require more than the clamp voltage of the current mirror input to be used.

The current limiters can be implemented using a number of devices. In one example, a resistor can be fabricated in CMOS using polysilicon or diffusion structures for each limiter. In another example, the limiters utilize a second diode in series with each current mirror where the limiting diode has a constricted channel or has a low doping concentration in its channel. In yet another example, the current limiters can be constructed from transistors with a gate voltage bias that puts the two transistors into the linear operating range for changes in source/drain voltage.

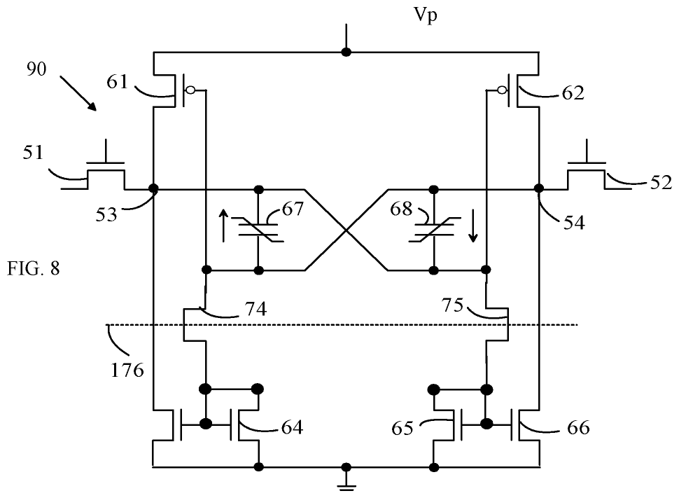

Refer now to FIG. 8, which illustrates another exemplary embodiment of a ferroelectric latch according to the present disclosure. Ferroelectric latch 90 utilizes a transistor that is biased into the linear operating range as discussed above. The transistors are shown at 74 and 75. To simplify the discussion, those elements of ferroelectric latch 90 that serve functions analogous to those served by corresponding elements in ferroelectric latch 80 have been given the same numeric designations and will not be discussed further here. The resistance provided by transistors 74 and 75 is controlled by the potential on a bias bus 176 that is connected to all of the ferroelectric latches in a circuit.

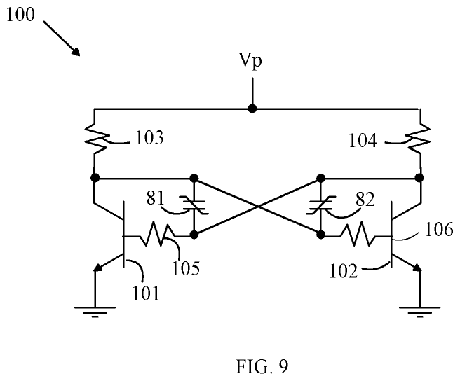

The above-described embodiments utilize CMOS based current controllers. However, current controllers based on other technologies can also be utilized to construct a ferroelectric latch according to the present disclosure. Refer now to FIG. 9, which illustrates a ferroelectric latch based on bipolar transistor technology. In ferroelectric latch 100, the current controllers shown in FIG. 5 are implemented with bipolar transistors 101 and 102, and the loads are implemented as resistors 103 and 104. To prevent the bipolar transistors from burning out at input voltages above the clamp voltage of the base-emitter junction, a resistor 105 is placed in series within the base to limit the current. This resistance is denoted by resistor 105. Hence, the bipolar embodiments do not necessarily require a separate current limiter. The diode junction 106 in the base of the bipolar transistors will clamp at a voltage that is approximately 0.7V; however, the resistor limits the current such that the ferroelectric capacitor terminal connected to the base can operate at a voltage above this clamp voltage.

Refer again to FIG. 5. In the above-described embodiments, the embodiments can be fabricated by constructing essentially all of the ferroelectric latch in a conventional semiconductor fabrication on a wafer and then constructing the ferroelectric capacitors either in the metal layers of that wafer or in a separate fabrication facility (FAB) that is adapted to deposit the ferroelectric capacitors. The ferroelectric capacitors typically utilize a dielectric layer constructed from a ferroelectric material that includes lead. Since lead contamination is of critical concern to most existing FABs, the deposition of the ferroelectric layers is typically performed in a different FAB for which the contamination is of less importance.

There are uses for the ferroelectric latch that are independent of conventional semiconductor circuits that are constructed on wafers in high volume FABs which utilize ultra small feature sizes. In this regard, it should be noted that the ferroelectric latch embodiments described above are asynchronous. That is, they do not need to change states at times specified by a clock signal. Accordingly, these ferroelectric latches are well adapted for such asynchronous circuits. In addition, there are circuits that require only a small number of such ferroelectric latches operating at relatively slow switching rates. The advantages of conventional high volume FABs are less important in these types of embodiments.

In one aspect of a ferroelectric latch according to the present disclosure, the current controllers, loads, and gates shown in FIG. 5 are fabricated in the same FAB that deposits the ferroelectric capacitors. To provide such embodiments, the ferroelectric latch utilizes FFETs that are fabricated using the same technology that is used for depositing the ferroelectric capacitors.

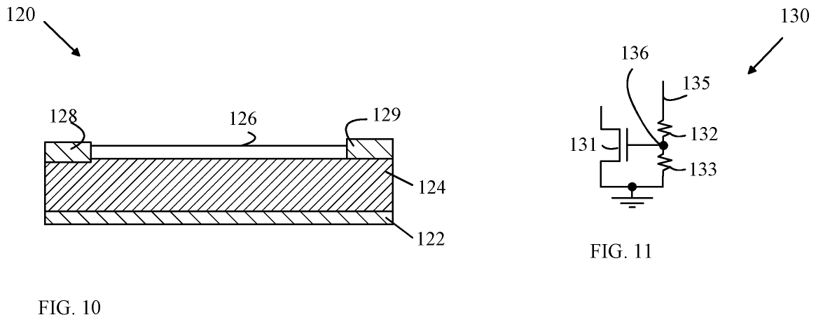

Refer now to FIG. 10, which is a cross-sectional view of one embodiment of a FFET 120 according to the present disclosure. In this exemplary embodiment, the FFET is constructed by first constructing a ferroelectric capacitor that includes bottom electrode 122, ferroelectric layer 124 and a top electrode. The top electrode is then etched to provide two contacts 128 and 129 that are separated from one another. A semiconductor layer 126 of semiconductor material is then deposited between the contacts. The top contacts become the source and drain of the FFET and the bottom contact becomes the gate of the FFET.

FFETs were originally used for data storage. The resistance between contacts 128 and 129 depends on the state of polarization of ferroelectric layer 124 and the type of semiconductor used for semiconductor layer 126. If an n-type semiconductor is used, the semiconductor layer will be depleted of carriers when the remanent polarization vector of ferroelectric layer 124 points away from bottom electrode 122. In this state, the resistance measured between contacts 128 and 129 will be much higher than that measured between these contacts when the ferroelectric layer is polarized in the opposite direction. It is this difference in resistance that is used to sense the state of polarization of ferroelectric layer 124 in memory applications. In memory applications, the state of polarization of ferroelectric layer 124 is set by applying a voltage between electrode 122 and contacts 128 and 129.

However, FFET 120 can also be operated in a mode that is analogous to a conventional FET. In this mode, contact 129 becomes the source, and contact 128 becomes the drain of the FFET, with electrode 122 being the gate. Consider the case in which the ferroelectric layer 124 is completely polarized in a direction away from electrode 122. An additional field generated by applying a voltage between electrode 122 and contact 129 in which contact 129 has a voltage that is greater than that on electrode 122 will not change the polarization of ferroelectric layer 124, since that layer already has its maximum polarization in that direction. The added electric field, however, does change the carrier density in semiconductor layer 126. Hence, an FFET can be used in applications that would normally utilize an FET.

Using an FFET for the current controllers shown in FIG. 5 presents problems analogous to those encountered when an FET is used to implement the current controller. An FFET is a voltage-to-current device. That is, the voltage on the gate controls the current between the source and drain. The current controllers require a current-to-current controller. Hence, a current-to-voltage converter is required at the input to the FFET.

In principle, a voltage divider could be utilized for the voltage-to-current controller. Refer now to FIG. 11, which illustrates a current controller that could, in principle, be used for the current controllers shown in FIG. 5. Current controller 130 is constructed from FFET 131 and a resistive divider consisting of resistors 132 and 133. A current that flows into terminal 135 generates a voltage at node 136 that is proportional to the current, and hence, the resistive divider provides the current-to-voltage function.

There are two problems with utilizing current controller 130 for the current controllers in the embodiments shown in FIG. 5. First, fabricating resistors presents additional challenges, particularly at small geometries. Second, variations in the resistors from location to location on a wafer can introduce additional problems.

Accordingly, the preferred current controllers, even with FFETs, are constructed as current mirrors as discussed above with respect to current controllers constructed from conventional FETs. The two FFETs of each current mirror are constructed in close proximity to one another, and hence, process variations across a wafer have a reduced impact on the resulting current controller. In addition, fabricating compact resistors is not required.

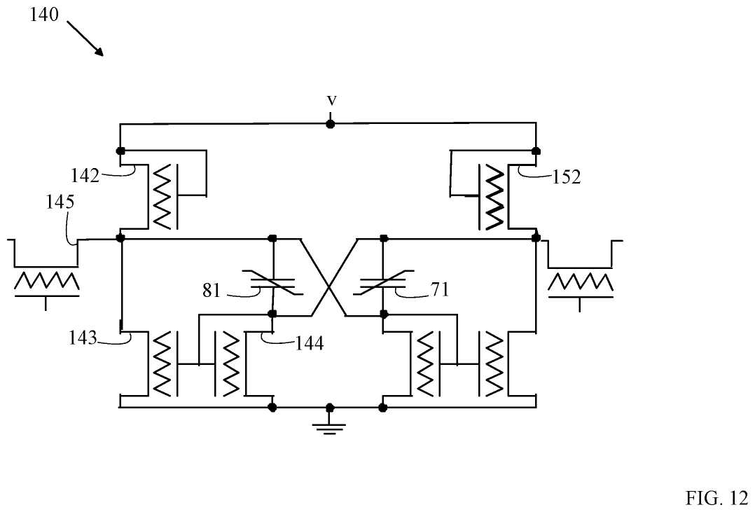

Refer now to FIG. 12, which illustrates a ferroelectric latch according one embodiment of the present disclosure. In ferroelectric latch 140, an FFET 142 with its drain connected to its base is used for load 84 shown in FIG. 5. Similarly, FFET 152 is used for load 79. The current controllers are implemented as current mirrors constructed from FFETs. For example, current controller 83 is constructed from FFETs 143 and 144. The gates are likewise constructed from FFETs. For example FFET 145 implements gate 88.

It should be noted that there are no separate current limiting components in ferroelectric latch 140. In ferroelectric latch 140, the FFETs do not have the high conduction values discussed above with respect to bipolar and CMOS transistors fabricated in silicon substrates. For instance, a 500 μm-wide-by-5 μm-long FFET can be constructed such that it has 2 kΩ of resistance when saturated ON. This level of internal resistance in this FFET whether used as a transistor or configured with its DRAIN shorted to its GATE to form a diode naturally limits conduction. As well, the six transistors used in the circuit above (the pull-up “diode”, the input diode of the current mirrors, and the power transistor of the current mirrors) can all be adjusted in their relative lengths and widths to achieve the desired ON/OFF voltage ratios and current limits.

As noted above, the non-volatile latch embodiments discussed above draw power as long as they are powered. This reflects the fact that a latch is a voltage-to-voltage device that accepts a voltage level as an input and generates an output signal which is also a voltage. The output voltage is related to the input voltage, and the last input state is stored in the latch. Ferroelectric capacitors are inherently charge controlled devices; hence, they require a voltage-to-charge converter to hold the output node at the low voltage for one of the two states, and this is the source of the power draw as long as the latch is powered.

In one aspect of a latch according to the present disclosure, a compound latch is constructed in which a non-volatile latch of the type discussed above is embedded in a conventional transparent latch that has been modified to store the current state of transparent latch in ferroelectric capacitors that are also shared by the embedded non-volatile latch. During normal operation, the embedded non-volatile latch is powered down in a manner in which the two ferroelectric capacitors in the non-volatile latch can still be written by the modified conventional latch, and hence, the ferroelectric capacitors store the current state of the modified conventional latch. It should be noted, that while the ferroelectric capacitors are written based on the current state of the modified conventional latch, the modified conventional latch cannot actually read the polarizations of the ferroelectric capacitors. However, during an interruption in power, these ferroelectric capacitors will have stored the last state of the modified conventional latch. When power is returned, the non-volatile latch is enabled and recovers the data stored in the ferroelectric capacitors to reset the state of the modified conventional latch. Once the state of the conventional latch has been recovered, the non-volatile latch will be powered down and the modified conventional latch will be enabled. In this manner, the excessive power draw of the non-volatile latch is avoided since it is only drawing power during a recovery from a power interruption.

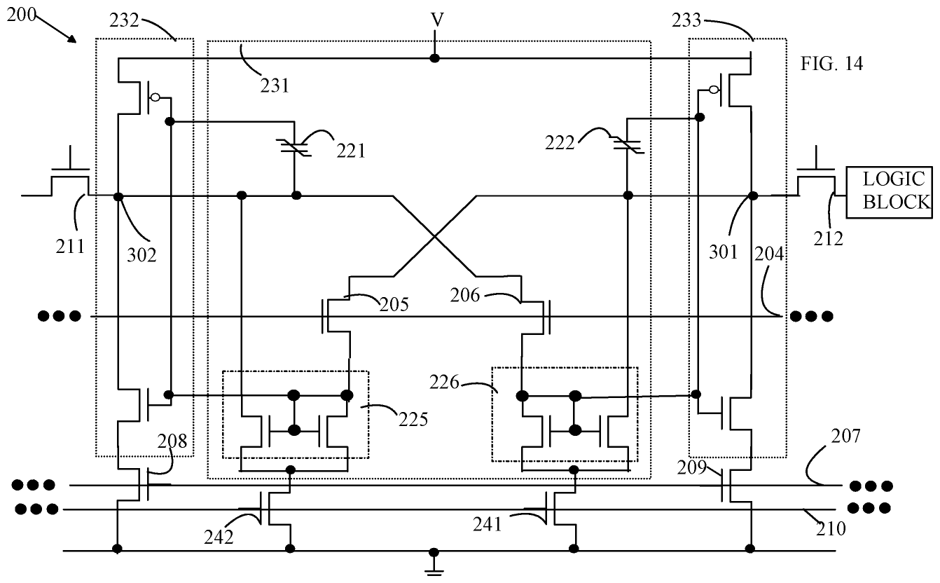

Refer now to FIG. 14, which illustrates a CMOS compound latch 200. The modified conventional latch comprises the two NOR gates 232 and 233. The embedded non-volatile latch is shown at 231. The two ferroelectric capacitors shown at 221 and 222 are shared between the conventional latch and the non-volatile latch 231. The current limiting transistors 205 and 206 provide the current limiting function for the current mirrors 225 and 226 of the non-volatile latch 231. Gates 208 and 209 control the modified conventional latch in response to signals on bus 207. When gates 208 and 209 are conducting, the modified conventional latch is enabled. When these gates are rendered non-conducting by the signal on bus 207, the modified conventional latch is disabled. Similarly, when gates 241 and 242 are rendered non-conducting by the signal of bus 210, the non-volatile latch 231 is disabled. In one aspect of a compound latch according to the present disclosure, buses 204, 207, and 210 are shared by a plurality of compound latches. Gates 211 and 212 can be used to isolate compound latch 200 during the recovery from a power interruption.

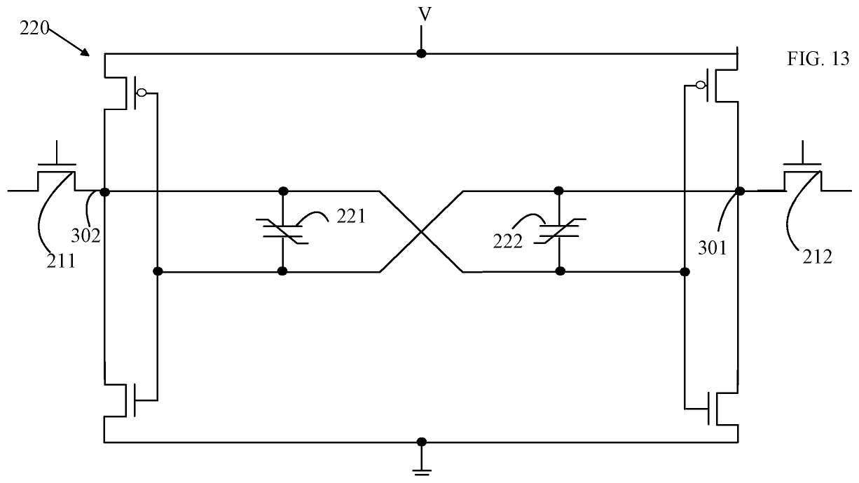

Compound latch 200 may be viewed as comprising three subunits shown at 232, 231 and 233. Subunits 232 and 233 implement the cross-connected gates used by the volatile latch 220 shown in FIG. 13. Subunit 231 is used to implement the ferroelectric latch portion of the circuit. Power to the subunits is controlled by two gates per subunit. The gates controlling power to the volatile latch are shown at 208 and 209 and controlled by the signal on bus 207. The gates controlling power to the nonvolatile latch are shown at 241 and 242 which are controlled by the signal level on bus 210.

When power returns after a power interruption, the volatile latch is rendered inoperative by biasing gates 208 and 209 to prevent the subunits from being powered. Power is then brought up on the ferroelectric latch 231 by using gates 241 and 242 to connect the two halves of the ferroelectric gate to power. Gates 205 and 206 operate in the current limiting mode in response to the signal on bus 204. As a result, the ferroelectric latch restores the voltages at the input and output of the ferroelectric latch. Once these voltages have stabilized, subunit 231 is then turned off by rendering gates 241 and 242 non-conducting. At this point, the volatile latch is powered and gates 205 and 206 are rendered fully conducting by the signal on bus 204. Since ferroelectric latch 231 is powered down, these gates provide the connections to the inputs of the volatile latch so that the cross coupled gates implemented in this latch configure the volatile latch shown in FIG. 13. Since subunit 231 is not drawing power, the ferroelectric latch only draws power when the compound latch is recovering from a power interruption.

The logic level signals must be sufficient to flip the polarizations of ferroelectric capacitors to 221 and 222 when the state of CMOS compound latches 200 changes. Given this limitation, the polarizations of ferroelectric capacitors to 221 and 222 will remain in opposing directions and follow the logic state of the modified conventional latch. When power is interrupted, CMOS compound latch 200 loses its current state; however that state is stored in the polarizations of ferroelectric capacitors 221 and 222. When power is returned, CMOS compound latch 200 cannot read the polarizations of ferroelectric capacitors 221 and 222 to reset the voltages at nodes 301 and 302 to their values before the power interruption, since that requires a charge source. Accordingly, when power returns, the modified latch is disabled by rendering gates 208 and 209 non-conducting, and activating the non-volatile latch by rendering gates 241 and 242 conducting. As noted above, non-volatile latch 231 effectively reads the polarizations of ferroelectric capacitors 221 and 222 and reestablishes the voltages at nodes 301 and 302 that existed prior to the power interruption. Once these voltages have been reestablished, the modified conventional latch is enabled by placing gates 208 and 209 in their conducting states. At this point, both the non-volatile latch 231 and the modified conventional latch are both enabled to allow the modified conventional latch to resume operations with the input and output voltages that were present at the time of the power interruption. Once the modified conventional latch is stabilized, the non-volatile latch 231 is disabled by rendering gates 241 and 242 non-conducting.

The compound latch shown in FIG. 14 is configured as a pass through latch that follows the state of the logic signals that enter node 302 and places the logic voltage specified by that state on node 301. In one aspect of a compound latch according to the present disclosure, the compound latch can also be used as non volatile shadow memory for storing and retrieving one of a plurality of one bit data values when input gate 211 is activated and a signal is present on the input to that gate.

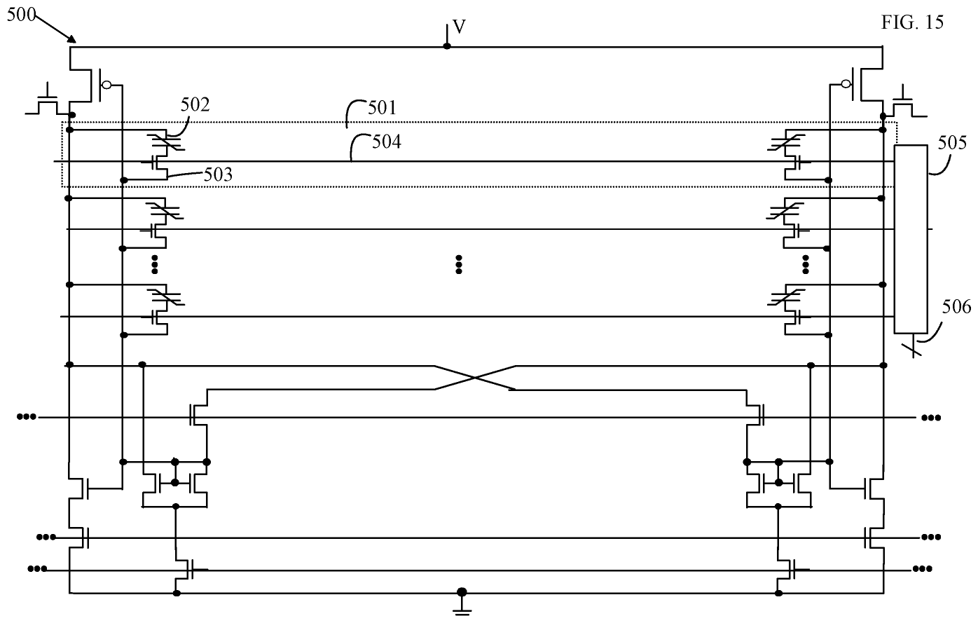

Refer now to FIG. 15, which illustrates an embodiment of a multiple bit compound latch 500 that can store and retrieve a plurality of data bits. Each data bit requires two ferroelectric capacitors. Compound latch 500 differs from CMOS compound latch 200 shown in FIG. 14 in that ferroelectric capacitors 221 and 222 have been replaced by a plurality of pairs of ferroelectric transistors. An exemplary pair of ferroelectric capacitors is shown at 501. Each capacitor is connected in series with a gate. The pair of ferroelectric capacitors is connected to the input and output of the NOR gate adjacent to that ferroelectric capacitor. An exemplary or electric capacitor is shown at 502 and the corresponding gate is shown at 503. While placing a signal on bus 504 that causes the gates to be conductive, the ferroelectric capacitors in the pair of ferroelectric capacitors are selected. The choice of which pair of ferroelectric capacitors is selected at any given time is determined by an encoder 505 that responds to an address signal on bus 506. At any given time, there is only one pair of ferroelectric capacitors that are connected to the input and outputs of the NOR gates.

The above example of a conventional latch is not based on two NOR gates. However, other forms of a conventional latch can be utilized. The simplest form of a conventional latch is two cross-connected inverters. The output of the first inverter is connected to the input of the second inverter, and the output of the other inverter is connected to the input of the first inverter. Other circuits that include the inverters can also be utilized. The modified conventional latch utilizes a first ferroelectric capacitor connected between the first inverter input and output. A second ferroelectric capacitor is connected between the second inverter input and output. The two ferroelectric capacitors are also utilized by the non-volatile latch.

The above-described embodiments of the present invention have been provided to illustrate various aspects of the invention. However, it is to be understood that different aspects of the present invention that are shown in different specific embodiments can be combined to provide other embodiments of the present invention. In addition, various modifications to the present invention will become apparent from the foregoing description and accompanying drawings.

What is claimed is:

1. A ferroelectric latch comprising
a first autonomous memory cell characterized by
a first current controller characterized by a first current controller input that controls a first current that flows between a first node and a power rail;
a first ferroelectric capacitor connected to said first node and said first current controller input; and
a first conductive load connected to said first node and a second power rail;
a second autonomous memory cell characterized by
a second current controller characterized by a second current controller input that controls a second current that flows between a second node and said power rail;
a second ferroelectric capacitor connected to said second node and said second current controller input; and
a second conductive load connected to said second node and said second power rail, said first node being connected to said second current controller input, and said second node being connected between said first current controller input and said second node.

2. The ferroelectric latch of claim 1 further comprising a first gate connected to said first node, said first gate connecting said first node to a signal line and being controlled by a device external to said ferroelectric latch.

3. The ferroelectric latch of claim 1 wherein said first and second current controllers comprise NPN transistors.

4. The ferroelectric latch of claim 1 wherein said first and second current controllers comprise CMOS transistors.

5. The ferroelectric latch of claim 4 wherein said first current controller comprises said CMOS transistors connected as a first current mirror.

6. The ferroelectric latch of claim 1 wherein said first and second current controllers comprise current mirrors.

7. The ferroelectric latch of claim 6 wherein said first current mirror is characterized by a clamp voltage and wherein said first current controller further comprises a current limiter that limits current entering said first current controller input, such that a maximum potential across said ferroelectric capacitors is greater than a clamp voltage of said current mirrors.

8. The ferroelectric latch of claim 1 wherein said first and second current controllers comprise bipolar transistors.

9. The ferroelectric latch of claim 2 wherein said first and second current controllers comprise FFETs.

10. The ferroelectric latch of claim 1 wherein said first and second current controllers comprise FFETs configured as a current mirror.

11. The ferroelectric latch of claim 1 wherein said first conducting load comprises an FFET.

12. The ferroelectric latch of claim 1 comprising
a first power gate configured to disconnect said ferroelectric latch from a first power rail in response to a first disconnect signal on a first bus.

13. The ferroelectric latch of claim 12 comprising
first and second latch gates, each of said latch gates having an input and an output, said input of said first latch gate being connected to said output of said second latch gate, and said output of said first latch gate being connected to said input of said second latch gate, said first ferroelectric capacitor being connected between said input and output of said first latch gate and said second ferroelectric capacitor being connected to said input and output of said second latch gate; and
a second power gate configured to disconnect said first latch gate from said first power rail in response to a second disconnect signal on a second bus.
